(19) United States
(12) Patent Application Publication
(10) Pub. No.: US 2006/0011968 A1
(43) Pub. Date: Jan. 19, 2006

(54) Semiconductor devices and methods of forming the same

(76) Inventors: Sung-Un Kwon, Gyeonggi-do (KR); Jae-Seung Hwang, Gyeonggi-do (KR)

Correspondence Address: MYERS BIGEL SIBLEY & SAJOVEC, PO BOX 37428, RALEIGH, NC, 27627, US

(21) Appl. No.: 11/169,086

(22) Filed: Jun. 28, 2005

(30) Foreign Application Priority Data
Jul. 16, 2004 (KR) 2004-55588

(51) Int. Cl. H01L 29/788; H01L 21/336

(52) U.S. Cl. 257/315; 438/257; 438/266; 257/316

(57) ABSTRACT

Methods of forming a semiconductor device include forming a structure including an oxide layer, a polysilicon layer and a mask layer on a substrate. The structure is etched to form an opening therein and the substrate beneath the opening to form a trench. An insulating structure is formed in the opening and the trench. The mask is removed and a second polysilicon layer is formed adjacent the second insulating structure. Sidewall portions of the second insulating structure are removed prior to formation of the second polysilicon layer. The thickness of the first polysilicon layer may be chosen based on the desired thickness of the second polysilicon layer. Resulting devices are also disclosed.

### CROSS REFERENCE TO RELATED APPLICATION

This application claims priority under 35 USC § 119 to Korean Patent Application No. 2004-55588 filed on Jul. 16, 2004, the disclosure of which is incorporated herein by reference in its entirety.

### BACKGROUND OF THE INVENTION

The present invention relates to methods for manufacturing semiconductor devices and resulting semiconductor devices. More particularly, the present invention relates to methods for manufacturing flash memory devices having polysilicon electrodes and resulting flash memory devices.

In conventional methods of manufacturing a flash memory device, a trench is formed at a surface portion of a substrate. An oxide layer and a polysilicon layer are then sequentially formed on the substrate. Portions of the oxide layer and the polysilicon layer are typically covered with a mask and selectively etched to define a tunnel oxide layer and a floating gate, respectively, above an active region of the substrate. Thereafter, a dielectric layer and a control gate may be sequentially formed on the floating gate.

However, alignment errors of masking layers may occur during the photolithography processes used for patterning the oxide layer and the polysilicon layer. When manufacturing a flash memory device including a fine pattern having a line width of about 70 nm or less, such alignment errors may occur more frequently. These alignment errors may cause damage to the active region during subsequent processes. For example, unwanted etching may cause pitting in the active region if, for example, an etch mask is misaligned.

A self-aligned process has been used to reduce the occurrence of alignment errors when forming conventional flash memory devices. In such a process, an active region on which the floating gate is to be formed and a field region to be filled with a trench isolation layer are generally simultaneously defined by a self-aligned process.

In a conventional self-aligned process, a pad oxide layer and a mask layer are generally sequentially formed on a substrate. A patterning process is performed on the pad oxide layer and the mask layer to selectively remove portions of the pad oxide layer and the mask layer, thereby forming a pad oxide layer pattern and a mask layer pattern, respectively. During the patterning process, a portion of the substrate beneath the removed portions of the pad oxide and mask layers is typically etched to form trenches in the substrate. As a result, an active region (between the trenches) and a field region (within the trenches) may be simultaneously defined. A film of insulating material is then generally formed on the substrate, filling the trench with the insulating material. Thereafter, the insulating film may be planarized until the mask layer pattern is exposed. The mask layer pattern and the pad oxide layer pattern are then typically sequentially removed so that the substrate is exposed. A tunnel oxide layer is then formed between the trenches on the exposed portions of the substrate. A polysilicon layer is- generally continuously formed on the tunnel oxide layer and the thin film. Thereafter, the polysilicon layer may be planarized until the remaining portions of the insulating film are exposed. Portions of the remaining portions of the insulating film are typically partially removed to form a trench isolation layer. The remaining portions of the polysilicon layer may form a floating gate. A dielectric layer and a control gate may be successively formed on the floating gate electrode and the trench isolation layer. The dielectric layer and the control gate may be patterned to define individual devices.

When a self-aligned process is used for forming a flash memory device, the occurrence of alignment errors may be reduced. However, a portion of the tunnel oxide layer (namely, the portion where the active region and the trench isolation layer are adjacent to each other), may be formed thinner than desired. In addition, voids may occur in the polysilicon layer due to the substantially low gap-filling margin typically associated with formation of polysilicon layers.

Examples of methods using a self-aligned process for forming a floating gate including a tunnel oxide layer and a polysilicon layer are disclosed in U.S. Pat. No. 6,620,681. However, the floating gate electrode in the '681 patent is divided into parts using generally complicated processes. In particular, the flash memory device of the '681 patent includes a buffer oxide layer pattern that requires substantial additional process steps to implement.

### SUMMARY

In some embodiments according to the invention, methods of forming a semiconductor device include forming an oxide layer, a first polysilicon layer and a mask layer on a substrate, selectively removing portions of the oxide layer, the first polysilicon layer and the mask layer to form an opening therein exposing a portion of the substrate, etching the portion of the substrate exposed through the opening to form a trench in the substrate beneath the opening, and depositing an insulating material in the opening and the trench to form a trench isolation structure. At least one sidewall portion of the trench isolation structure may be removed and a second polysilicon layer formed on the first polysilicon layer and a sidewall of the trench isolation structure.

In some embodiments, after forming the second polysilicon layer, an upper portion of the trench isolation structure may be removed to thereby form an isolation layer.

In some embodiments a width of about 50Å to about 500Å may be removed from a sidewall portion. Consequently, in devices in which the active region is defined by a pair of adjacent trench isolation structures, the width of the second polysilicon layer may have a width of from about 100Å to 1000Å greater than a width of the active region. In some embodiments, the width of the second polysilicon layer may have a width of from about 100Å to 500Å greater than a width of the active region.

In some embodiments of the invention, the first polysilicon layer has an initial thickness of about 400Å to about 800Å. In some embodiments, a portion of the first polysilicon layer is removed prior to formation of the second polysilicon layer. In some embodiments about 200Å to 300Å of the first polysilicon layer may be removed.

In some embodiments, the first polysilicon layer and the mask layer have a combined thickness of at least about 1000Å.

In some embodiments, the second polysilicon layer has a thickness equal to the difference between about 1000Å and the thickness of the first polysilicon layer.

In some embodiments according to the invention, the second polysilicon layer is formed on the first polysilicon layer and the trench isolation structure. The second polysilicon layer may be thinned until the trench isolation structure is exposed. In some embodiments, thinning may be performed by chemical mechanical polishing the second polysilicon layer until the trench isolation layer is exposed. Accordingly, a thickness of the second polysilicon layer may be determined by a height of the trench isolation structure.

In some embodiments, a dielectric layer is formed on the second polysilicon layer and the isolation layer and a third polysilicon layer is formed on the dielectric layer. The first and second polysilicon layers may thereby form a floating gate electrode of a flash memory device, while the second polysilicon layer may form a control electrode of a flash memory device.

In some embodiments according to the invention, methods of forming a semiconductor device include forming an oxide layer, a first polysilicon layer and a mask layer on a substrate, selectively removing portions of the oxide layer, the first polysilicon layer and the mask layer to form a pair of openings therein exposing portions of the substrate, forming trenches in the substrate beneath the pair of openings, depositing an insulating material in the openings and the trenches to form a pair of trench isolation structures, removing the mask layer, removing sidewall portions of the trench isolation structures, and forming a second polysilicon layer on the first polysilicon layer between the trench isolation structures.

In some embodiments of the invention, a width of about 50Å to about 500Å may be removed from each of the trench isolation structures. Embodiments of the invention may further include removing upper portions of the trench isolation structures after forming the second polysilicon layer, to thereby form an isolation layer, forming a dielectric layer on the first electrode and the isolation layer, and forming a gate electrode on the dielectric layer.

Semiconductor devices according to embodiments of the invention include flash memory devices having a semiconductor substrate, a trench isolation layer defining an active region of the substrate, a tunneling oxide layer formed on the active region of the substrate, a first polysilicon layer formed on the tunneling oxide, and a second polysilicon layer formed on the first polysilicon layer. In some embodiments according to the invention, the second polysilicon layer has a width about 100Å to 1000Å greater than a width of the active region. In some embodiments according to the invention, the second polysilicon layer has a width about 100Å to 500Å greater than a width of the active region. The first polysilicon layer and the second polysilicon layer may together form a first electrode of an electronic device. The first electrode may have a thickness of about 1000Å or greater.

In some embodiments, devices according to the invention further include a dielectric layer on the second polysilicon layer, and a third polysilicon layer on the dielectric layer, the third polysilicon layer forming a second electrode of an electronic device.

In some embodiments, the first electrode has a sidewall, and the dielectric layer and the third polysilicon layer extend along the sidewall of the first electrode to the trench isolation layer.

Embodiments according to the invention include methods of manufacturing semiconductor devices that may prevent or reduce the occurrence of thinning in tunnel oxide layers using a self-aligned manufacturing process. Some embodiments of the invention include methods for reducing or preventing the occurrence of voids in polysilicon layers due to a deficient gap-filling margin in a self-aligned process.

### BRIEF DESCRIPTION OF THE DRAWINGS

FIGS. 1 to 7 are cross-sectional views illustrating methods of manufacturing a semiconductor device in accordance with some embodiments of the invention.

### DETAILED DESCRIPTION OF EMBODIMENTS ACCORDING TO THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on” or “connected to” another element or layer, it can be directly on or directly connected to the other element or layer or intervening elements or layers may be present.

Like reference numerals refer to like elements throughout. As used herein the term “and/or” includes any and all combinations of one or more of the associated listed items.

It will be understood that, although the terms first, second, etc. may be used herein to describe various elements, components or layers, these elements, components or layers should not be limited by these terms. These terms are only used to distinguish one element, component or layer from another element, component or layer. Thus, a first element, component or layer discussed below could be termed a second element, component or layer without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. It will also be appreciated by those of skill in the art that references to a structure or feature that is disposed “adjacent” another feature may have portions that overlap or underlie the adjacent feature.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, elements or components, but do not preclude the presence or addition of one or more other features, elements or components.

Embodiments of the present invention are described herein with reference to cross-section (and/or plan view) illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated or described as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

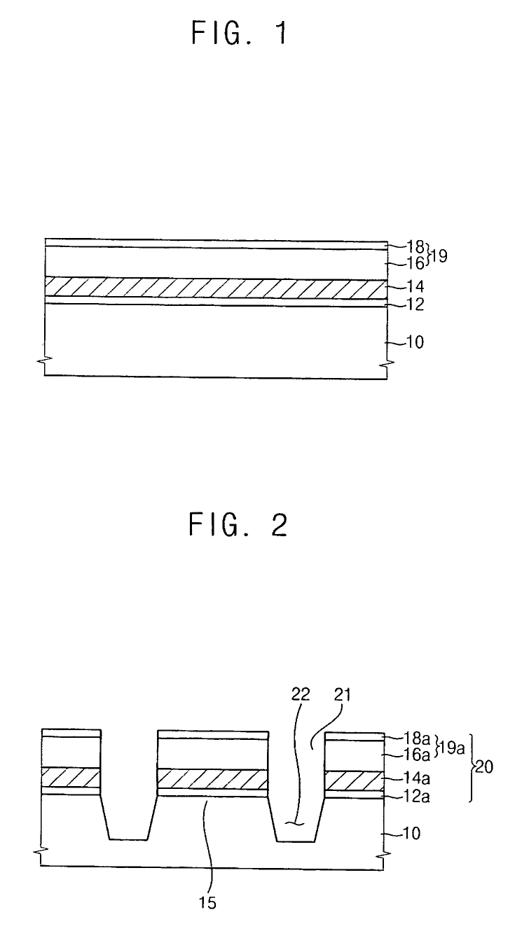

Various embodiments of the invention will now be described with reference to the accompanying drawings. FIGS. 1 to 7 are cross-sectional views illustrating methods of manufacturing semiconductor devices and resulting devices in accordance with some embodiments of the invention. Referring to the embodiments of FIG. 1, a tunnel oxide layer 12 is formed on a semiconductor substrate 10. The substrate 10 may be a silicon substrate, a silicon-on-insulator (SOI) substrate, or any other suitable substrate.

The tunnel oxide layer 12 may include silicon oxide. The tunnel oxide layer 12 may be formed by a thermal oxidation process and/or a radical oxidation and/or another deposition process. The tunnel oxide layer 12 may have a thickness of about 10Å to about 500Å. In some embodiments, the thickness of the tunnel oxide layer 12 is about 50Å to about 300Å. In some embodiments, the thickness of the tunnel oxide layer 12 is about 50Å to about 200Å. In some embodiments, the thickness of the tunnel oxide layer 12 is about 100Å. In some embodiments, the tunnel oxide layer 12 is formed before a trench isolation layer is formed by subsequent processes. Thus, thinning of the tunnel oxide layer 12 may be reduced or avoided near an interface between an active region and the trench isolation layer.

A first preliminary polysilicon layer 14 is formed on the tunnel oxide layer 12 in the embodiment of FIG. 1. The first preliminary polysilicon layer 14 may be formed by a first process for deposition and a second process for doping the polysilicon layer 14 with an impurity. The deposition process and the doping process may be carried out sequentially or simultaneously. Moreover, in cases where the processes are performed sequentially, the doping process may be performed in the same chamber as the deposition process was performed (in-situ) and/or in a different chamber (ex-situ).

The deposition process for the first preliminary polysilicon layer 14 may be a plasma enhanced chemical vapor deposition (PECVD) process. However, polysilicon deposited using known PECVD processes may not possess desired electrical characteristics. Thus, in some embodiments, the first preliminary polysilicon layer 14 may be deposited by thermal decomposition of silane (SiH₄). A furnace may be used for dissociating silane (SiH₄) in such a process. The silane gas may be a pure silane gas and/or a silane gas diluted with nitrogen. The diluted silane gas may have about 20 percent by weight to about 30 percent by weight of silane. When such a process is performed at a temperature of under about 500° C., the deposition rate of polysilicon may be undesirably low. When such a process is performed at a temperature of over about 650° C., the silane gas may rapidly decompose, which may result in poor uniformity of the deposited polysilicon layer. Thus, in some embodiments, the deposition process may be performed at a temperature of about 500° C. to about 650° C. When the deposition process is performed at a temperature of about 500° C. to about 650° C., the deposition rate of the polysilicon may be satisfactory at a pressure of about 25 Pa to about 150 Pa.

The doping process for the first preliminary polysilicon layer 14 may be a diffusion process, an ion implantation process and/or an in-situ doping process. A diffusion doping process may be performed after the first (deposition) process. An ion implantation process and/or an in-situ doping process may be performed simultaneously with the first (deposition) process. The in-situ doping process may use an impurity gas. An impurity used in the doping process may be phosphorus (P), arsenic (As), boron (B) and/or indium (In). These may be used alone or in a mixture thereof. When the impurity is phosphorus, an N-type gate electrode may be formed. When the impurity is boron, a P-type gate electrode may be formed.

For typical active area widths, the thickness of a polysilicon deposition may be limited by the gap-filling margin of the deposited material. If an active area with a depth of over about 800Å is filled with polysilicon, one or more voids may form in the polysilicon layer as a result of an insufficient gap-filling margin.

In some embodiments of the invention, the first preliminary polysilicon layer 14 may have a thickness less than 800Å. As described in greater detail below, a second polysilicon layer 24 may be deposited on the first preliminary polysilicon layer 14, the first preliminary polysilicon layer 14 and the second preliminary polysilicon layer 24 together forming a first gate electrode having a thickness greater than 800Å.

In some embodiments, in order to reduce or avoid the occurrence of voids during deposition of the second polysilicon layer 24, the thickness of the first preliminary polysilicon layer 14 may be selected based on a thickness of the second polysilicon layer 24.

As noted above, if a narrow recess having a depth of over about 800Å is filled with the second polysilicon layer 24, a void due to an insufficient gap-filling margin of the second polysilicon layer 24 may be formed in the narrow recess. However, to provide a polysilicon gate electrode having electrical characteristics desired for use as a floating gate, it may be desirable for the gate electrode to have a height of about 1,000Å. In some embodiments of the invention, the gate electrode may be formed in a recess having a depth of about 1,000Å or more.

After deposition of the first preliminary polysilicon layer 14, a thickness of about 200Å to 300Å of the first preliminary polysilicon layer 14 may be removed by subsequent processes to form a first polysilicon layer 14a having a thickness thinner than that of the first preliminary polysilicon layer 14. Thus, in some embodiments, the first preliminary polysilicon layer 14 may have a thickness of about 400Å to 800Å. In some embodiments, the first preliminary polysilicon layer 14 may have a thickness of about 450Å to 550Å. In some embodiments, the first preliminary polysilicon layer 14 may have a thickness of about 500Å.

Referring to the embodiments illustrated in FIG. 1, a mask layer 19 is formed on the first preliminary polysilicon layer 14. The mask layer 19 may be a single-layered structure including a silicon nitride layer or a middle temperature oxide (MTO) layer. In some embodiments, the mask layer 19 may be a multi-layered structure, for example, a double-layered structure including both a silicon nitride layer and an MTO layer. As illustrated in FIG. 1, the mask layer 19 is a double-layered structure including a silicon nitride layer 16 and an MTO layer 18.

An antireflective coating layer may be formed on the mask layer 19 so that a sequential photolithography process may be more easily performed. The antireflective coating layer may include silicon oxynitride.

Referring now to the embodiments of FIG. 2, the tunnel oxide layer 12, the first preliminary polysilicon layer 14 and the mask layer 19 are patterned, for example by a photolithography process, to form a first structure 20 including a patterned tunnel oxide layer 12a above an active region 15, a patterned first preliminary polysilicon layer 14a and a patterned mask layer 19a. The first structure 20 shown in FIG. 2 has an opening 21 partially exposing the substrate 10 therethrough. The mask layer 19a shown in FIG. 2 includes a patterned silicon nitride layer 16a and a patterned MTO layer 18a.

A portion of the substrate 10 exposed through the opening 21 is etched using the first structure 20 as an etch mask. Thus, a trench 22 is formed at a surface portion of the substrate 10. A portion of the substrate 10 positioned under the first structure 20 and between the trenches 22 is an active region 15. That is, the trench 22 and the active region 15 may be simultaneously defined by a self-aligned process. Thus, a desired alignment tolerance may be achieved. The trench 22, which corresponds to a field region, isolates the active regions of adjacent devices.

An optional oxidation process, such as a thermal oxidation, may be performed to oxidize a sidewall of the trench 22. This may at least partially repair damage to an etched surface of the substrate 10.

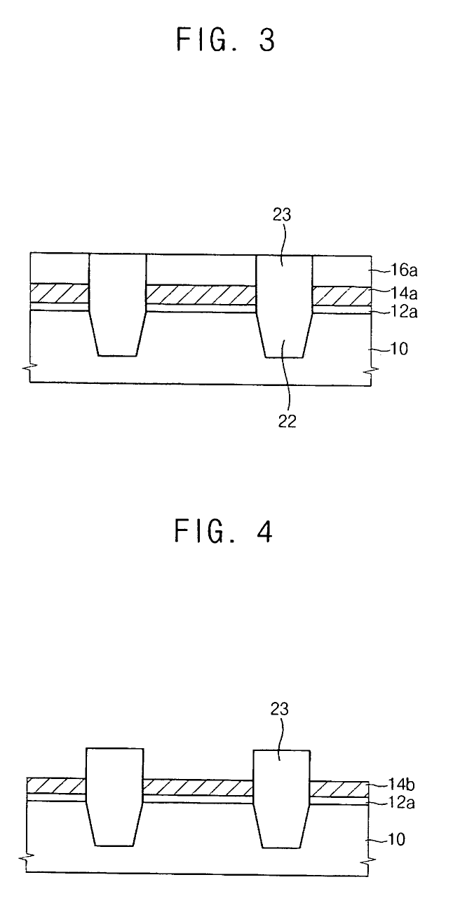

Referring now to the embodiments of FIG. 3, a thin film of insulating material is blanket deposited on the substrate such that trench 22 and opening 21 are filled with the insulating material. The insulating material may be a high-density plasma oxide layer having good gap-filling characteristics. The thin film of insulating material is then partially removed until the silicon nitride layer 16a is exposed. In some embodiments, the thin film of insulating material is planarized by a chemical mechanical polishing process until the silicon nitride layer 16a is exposed. A preliminary second structure 23 including the insulating material is thereby formed in the opening 21 and the trench 22.

As shown in the embodiments of FIG. 4, the silicon nitride layer 16a is then removed by a wet etching process using an etchant such as phosphoric acid so that the first preliminary polysilicon layer 14a is exposed. During the wet etching process, the first preliminary polysilicon layer 14a may be partially etched to form a patterned first polysilicon layer 14b that is thinner than the first preliminary polysilicon layer 14a.

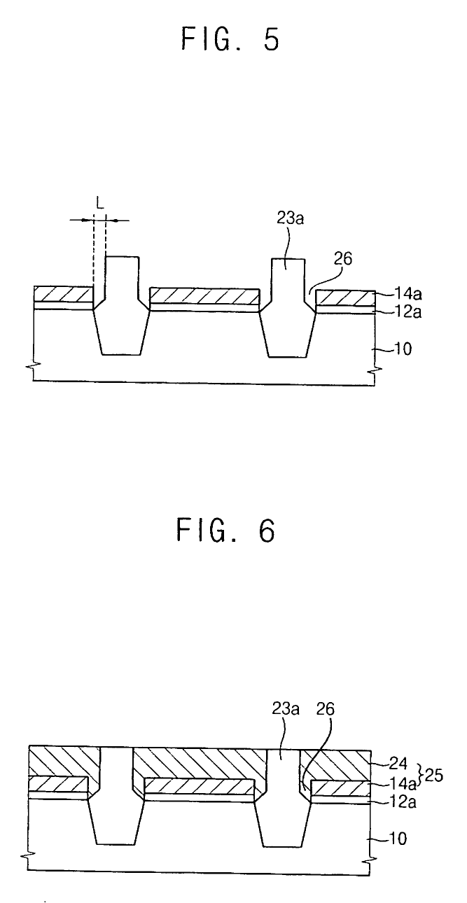

Referring now to the embodiments of FIG. 5, sidewall portions of the preliminary second structure 23 are partially removed to form a second structure 23a. In some embodiments, the sidewall portions of the preliminary second structure 23 are removed by an isotropic etch such as a wet etch using, for example, dilute HF, BOE or other suitable etchant. Such an etch process may result in a reduction in the height of preliminary second structure 23a. As will be appreciated by those skilled in the art, the height of the preliminary second structure 23 (which is determined by a thickness of the silicon nitride layer 16a as described above) may be chosen such that the height of the second structure 23a is appropriately defined after the removal of the sidewall portions of preliminary second structure 23. As will be described below, the height of the second structure 23a defines a thickness of the first gate electrode.

As further seen in the embodiments of FIG. 5, the sidewall portion may be removed to a width “L”. In some embodiments, the width “L” may be about 50Å to about 500Å. In some embodiments, the width “L” is about 50Å to about 250Å. Because the sidewall portion is removed to a width “L”, a width of a region where the second polysilicon layer pattern is to be formed may increase. That is, the expanded region between adjacent second structures 23a increases the width of the first gate electrode including the second polysilicon layer pattern so that the first gate electrode formed in the region has electrical characteristics desired for use as a floating gate. In addition, because the second polysilicon layer pattern is formed in the expanded region, the active region may be desirably protected while a dielectric layer and a control gate are subsequently formed and patterned.

Referring now to the embodiments of FIG. 6, a second polysilicon layer 24 is formed on the first polysilicon layer 14b and the second structure 23a. The second polysilicon layer 24 is planarized, for example by a chemical mechanical polishing (CMP) process, until the second structure 23a is exposed, thereby forming a second polysilicon layer 24. As a result, a first gate electrode 25 including the polysilicon layer 14b and second polysilicon layer 24 may be formed on the tunnel oxide layer 12a. The first gate electrode 25 may be a floating gate.

The second polysilicon layer 24 may fill a space formed when a portion of the first preliminary polysilicon layer 14a is removed following removal of the silicon nitride layer pattern 16a. As described above, the first polysilicon layer 14b may have a thickness substantially thinner than the preliminary polysilicon layer 14a, so that the second polysilicon layer 24 may efficiently fill up the recess 26 defined by the second structure 23a, the first polysilicon layer 14b and the tunnel oxide layer 12a. Thus, the second polysilicon layer 24 may fill the recess 26, which may reduce or prevent the generation of voids in the polysilicon layer 24. Stated differently, reducing the thickness of first preliminary polysilicon layer 14a reduces the depth of recess 26, which may permit the second polysilicon layer 24 to fill recess 26 without the formation of undesirable voids in the polysilicon layer 24.

The second polysilicon layer 24 may also fill the portion of the second preliminary structure 23 removed as described above. Thus, the width of the second polysilicon layer pattern 24 may be increased compared to the width of the active region. In some embodiments, the second polysilicon layer 24 has a width about 100Å to 500Å greater than a width of the active region. In some embodiments, the second polysilicon layer 24 has a width about 100Å to 1000Å greater than the width of the active region 15.

As illustrated in the embodiments of FIG. 6, the second polysilicon layer 24 may extend into recess 26 along the sidewalls of first polysilicon pattern 14b where the sidewall portions of second preliminary structure 23 were removed. As noted above, relative dimensions of the features illustrated in the figures are exaggerated for ease of explanation. As will be appreciated by those skilled in the art, in some embodiments of the invention, the second polysilicon layer 24 should not contact the substrate 10, or the first gate electrode may become short-circuited and cease to function properly as a floating gate.

The composition of the second polysilicon layer 24 may be similar to that of the first preliminary polysilicon layer 14. Therefore, processes performed to form the second polysilicon layer may be substantially similar to those performed to form the first preliminary polysilicon layer 14.

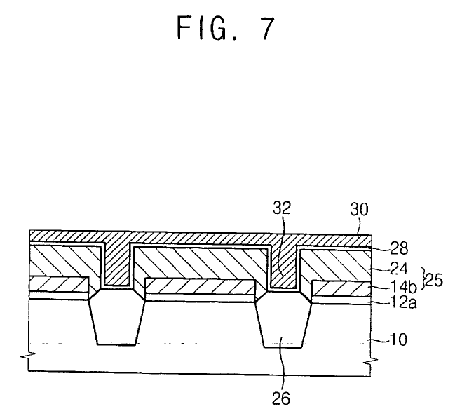

Referring now to the embodiments of FIG. 7, an upper portion of the second structure 23a is removed, leaving a trench isolation layer 26 in the trench 22. Removing the upper portion of the second structure 23a also results in formation of a trench 32 adjacent the second polysilicon layer having a depth of at least about a thickness of the second polysilicon layer. Dielectric layer 28 is then continuously formed on the first electrode 25 and the trench isolation layer 26. Thus, the first gate electrode 25 may be divided into parts that are electrically insulated from each other. As illustrated in the embodiments of FIG. 7, the dielectric layer 28 extends down a sidewall of the first gate electrode 25 to the trench isolation layer 26 in the region from which the upper portion of the second structure 23a was removed.

The dielectric layer 28 may be an oxide-nitride-oxide (ONO) layer or a metal oxide layer having a high dielectric constant. The metal oxide layer may be a hafnium oxide layer and/or a titanium oxide layer. The metal oxide layer may be formed by an atomic layer deposition process.

A second gate electrode 30 corresponding to the control gate may be formed on the dielectric layer 28. The second gate electrode 30 may be a polysilicon layer doped with impurities. The composition of the polysilicon layer may be similar to that of the first preliminary polysilicon layer 14. Therefore, the polysilicon layer for the second gate electrode 30 may be formed by processes similar to those performed to form the first preliminary polysilicon layer 14.

The dielectric layer 28 and the second gate electrode 30 may be patterned to form a cell of a flash memory device. The cell includes a floating gate, dielectric layer 28 and a control gate. The floating gate corresponds to the first gate electrode 25, while the control gate corresponds to the second gate electrode 30.

According to some embodiments of the invention, the thickness of a first preliminary polysilicon layer may be selected taking into consideration a desired thickness of a second polysilicon layer pattern positioned at an upper portion of a flash memory device. Thus, the gap-filling margin of the second polysilicon layer pattern may be improved. Furthermore, a region in which the second polysilicon layer pattern is to be formed may be expanded so that a first gate electrode including the first polysilicon layer and the second polysilicon layer pattern has electrical characteristics desired for use as a floating gate. As a result the yield and reliability of the resulting flash memory device may be improved.

Embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming a semiconductor device comprising:
forming an oxide layer, a first polysilicon layer and a mask layer on a substrate;
selectively removing portions of the oxide layer, the first polysilicon layer and the mask layer to form an opening therein exposing a portion of the substrate;
etching the portion of the substrate exposed through the opening to form a trench in the substrate beneath the opening;
depositing an insulating material in the opening and the trench to form a trench isolation structure;
removing the mask layer;
removing a sidewall portion of the trench isolation structure; and
forming a second polysilicon layer on the first polysilicon layer and a sidewall of the trench isolation structure.

2. The method of claim 1, further comprising:
removing a portion of the first polysilicon layer prior to forming the second polysilicon layer.

3. The method of claim 1, wherein forming a second polysilicon layer comprises forming the second polysilicon layer on an upper surface of the trench isolation structure, and thinning the second polysilicon layer until the upper surface of the trench isolation structure is exposed.

4. The method of claim 1, further comprising:
forming a dielectric layer on the second polysilicon layer and the isolation layer; and
forming a third polysilicon layer on the dielectric layer,
wherein the first and second polysilicon layers form a floating gate of a flash memory device and the third polysilicon layer forms a control gate of a flash memory device.

5. The method of claim 1, further comprising:
removing an upper portion of the trench isolation structure after forming the second polysilicon layer.

6. The method of claim 5, wherein removing a sidewall portion of the trench isolation structure comprises reducing the width of the trench isolation structure by a predetermined distance L.

7. The method of claim 5, wherein removing a sidewall portion of the trench isolation structure comprises removing a width of about 50Å to about 1000Å from the sidewall of the trench isolation structure.

8. The method of claim 7, wherein removing a sidewall portion of the trench isolation structure comprises removing a width of about 50Å to about 500Å from the sidewall of the trench isolation structure.

9. The method of claim 5, further comprising:
removing an upper portion of the trench isolation structure after forming the second polysilicon layer to form an isolation layer;
forming a dielectric layer on the first electrode and the isolation layer; and
forming a second gate electrode on the dielectric layer.

10. The method of claim 3, wherein thinning the second polysilicon layer comprises etching the second polysilicon layer.

11. The method of claim 3, wherein thinning the second polysilicon layer comprises planarizing the second polysilicon layer by chemical mechanical polishing.

12. The method of claim 1, wherein selectively removing portions of the oxide layer, the first polysilicon layer and the mask layer comprises etching the oxide layer, the first polysilicon layer and the mask layer.

13. The method of claim 2, wherein the first polysilicon layer has an initial thickness of about 400Å to about 800Å, and removing a portion of the first polysilicon layer comprises removing about 200Å to 300Å of the first polysilicon layer.

14. The method of claim 2, wherein the first polysilicon layer and the mask layer have a combined thickness of at least about 1000Å.

15. The method of claim 13, wherein the second polysilicon layer has a thickness equal to a difference between about 1000Å and the thickness of the first polysilicon layer.

16. The method of claim 5, wherein removing a portion of the trench isolation structure comprises forming a trench adjacent the second polysilicon layer.

17. The method of claim 16 , wherein the formed trench has a depth of at least about a thickness of the second polysilicon layer.

18. A method of forming a semiconductor device comprising:
forming an oxide layer, a first polysilicon layer and a mask layer on a substrate;
selectively removing portions of the oxide layer, the first polysilicon layer and the mask layer to form a pair of openings therein exposing portions of the substrate;
forming trenches in the substrate beneath the pair of openings;
depositing an insulating material in the openings and the trenches to form a pair of trench isolation structures;
removing the mask layer;
removing sidewall portions of the trench isolation structures; and
forming a second polysilicon layer on the first polysilicon layer between the pair of trench isolation structures.

19. The method of claim 18, wherein removing sidewall portions of each of the pair of trench isolation structures comprises removing a width of about 50Å to about 250Å from a sidewall of each of the trench isolation structures.

20. The method of claim 18, wherein removing sidewall portions of the trench isolation structures comprises removing a width of about 50Å to about 500Å from a sidewall of each of the pair of trench isolation structures.

21. The method of claim 18, further comprising:
removing an upper portion of each of the pair of trench isolation structures after forming the second polysilicon layer, to form a isolation layers;
forming a dielectric layer on the second polysilicon layer and the isolation layer; and
forming a gate electrode on the dielectric layer.

22. A flash memory device, comprising:
a semiconductor substrate;
a trench isolation layer defining an active region of the substrate;
a tunneling oxide layer on the active region of the substrate;
a first polysilicon layer on the tunneling oxide; and
a second polysilicon layer formed on the first polysilicon layer;
wherein the second polysilicon layer has a width about 100Å to 1000Å greater than a width of the active region; and
wherein the first polysilicon layer and the second polysilicon layer together form a floating gate electrode.

23. The device of claim 22, wherein the second polysilicon layer has a width about 100Å to 500Å greater than a width of the active region.

24. The device of claim 22, wherein a thickness of the first electrode is at least about 1000Å.

25. The device of claim 22, further comprising:
a dielectric layer on the second polysilicon layer; and
a third polysilicon layer on the dielectric layer.

26. The device of claim 25, wherein the first electrode has a sidewall and
wherein the dielectric layer and the third polysilicon layer extend along the sidewall of the first electrode to the trench isolation layer.
